(19) United States
(12) Patent Application Publication
(10) Pub. No.: US 2023/0269904 A1
(43) Pub. Date: Aug. 24, 2023

(54) AIR MOVING DEVICE CONTROLS BASED ON USER SELECTED NOISE LEVELS

(71) Applicant: HEWLETT-PACKARD DEVELOPMENT COMPANY, L.P., Spring, TX (US)

(72) Inventors: Andrew Wiltzius, Fort Collins, CO (US); James Douglas, Fort Collins, CO (US)

(21) Appl. No.: 17/676,728

(22) Filed: Feb. 21, 2022

(51) Int. Cl. H05K 7/20; G06F 11/30; G06F 1/20

(52) U.S. Cl. CPC H05K 7/20209; H05K 7/20172; G06F 11/3058; G06F 1/206

(57) ABSTRACT

In example implementations, an apparatus is provided. The apparatus includes an air moving device to cool the apparatus, a memory, and a processor. The memory is to store an operational speed-to-noise correlation of the air moving device. The processor is communicatively coupled to the air moving device and the memory. The processor is to receive a noise level selected by a user, determine an operational speed of the air moving device based on the noise level selected by the user and the operational speed-to-noise correlation of the air moving device, and control the air moving device to operate at the operational speed that is determined.

### BACKGROUND

Computing devices can be used to execute various applications and programs. A processor is deployed in a computing device to execute the applications and programs. The computing device can have additional components that can help execute the applications, such as memory, graphics processors, and the like.

As the computing device operates, the various components can generate heat. The computing device can include various ways to dissipate heat away from the components in the computing device. For example, the computing device may include various air moving devices to help cool the computing device during operation to prevent overheating of the various components within the computing device.

### BRIEF DESCRIPTION OF THE DRAWINGS

FIG. 1 is a block diagram of an example an apparatus with an air moving device controlled by speed controls of the present disclosure;

FIG. 2 is another block diagram of an example apparatus with the air moving device controlled by speed controls of the present disclosure;

FIG. 3 is another block diagram of the example apparatus with the air moving device controlled by speed controls of the present disclosure in an example environment;

FIG. 4 is a flow chart of an example method to control a speed of an air moving device of a computing device based on a user selected noise level of the present disclosure; and

FIG. 5 is an example non-transitory computer readable storage medium storing instructions executed by a processor to control a speed of an air moving device of a computing device based on a user selected noise level of the present disclosure.

### DETAILED DESCRIPTION

Examples described herein provide an apparatus and method to control the speed of air moving devices of a computing device based on user selected noise levels. As discussed above, computing devices can be used to execute various applications and programs. A computing device can include various ways to dissipate heat away from the components in the computing device. For example, the computing device may include various air moving devices to help cool the computing device during operation to prevent overheating of the various components within the computing device.

However, the operation of the air moving devices can generate a large amount of noise that can be distracting to the user. Different types of air moving devices, as well as different models of air moving devices, can have different noise profiles based on the operational speeds of the air moving devices. In addition, other components can create noise as well. For example, mechanical hard disk drives can generate noise.

Currently, some computing devices may provide a user with some limited pre-set options for limiting the noise generated by the computing devices. For example, a computing device may provide a performance mode or a silent mode. The performance mode may allow for a maximum amount of noise to allow the air moving devices to run at a fastest operational speed to cool the processor and/or graphics processor. The silent mode may limit the operation of the processor and/or graphics processor to prevent overheating such that the air moving devices may be kept off or run at a relatively low operational speed.

Providing this limited number of options may be insufficient for some users. In addition, the limited number of options may not take into consideration existing background noise in an environment. For example, a user may want to have a desired level of noise, but the environment in which the computing device is located may have a large amount of background noise. As a result, the air moving devices may be allowed to operate at a slightly louder level than the level selected by the user, since the additional noise may be undiscernible from the background noise.

The present disclosure allows the speed of an air moving device to be controlled based on a desired noise level selected by a user. The noise level may be selected from a range of predetermined selectable noise level values (e.g., a noise level between 1 and 10). In another example, the range of noise values from different operational speeds of the air moving device may be presented to the user, and the user may select the desired noise level by cycling through the operational speeds of the air moving device.

Once the noise level is selected, the speed of the air moving device may be determined based on a pre-measured speed-to-noise correlation for the air moving device. A speed-to-noise correlation may be premeasured for different types of air moving devices or different models of air moving devices.

In an example, where multiple air moving devices and/or components may contribute to the noise level, a function may be applied that totals the noise based on a weighted contribution of each noise source. Different components may be weighted differently based on the relative importance of the components to the operation of the computing device.

In another example, the weighting of the contribution from each noise source may be dynamically changed during operation of the computing device. For example, an air moving device for the CPU may be the most critical component to maintain a high level of operation for the computing device. As the computing device operates, the CPU may begin to overheat. Thus, the air moving device for the CPU may run at a faster speed. To accommodate the faster speed, the weighting of the CPU air moving device may be increased and the weighting of other components may be decreased to maintain the noise level selected by a user.

Lastly, the computing device may automatically compensate for the user selected noise level based on background noise detected in the environment of the computing device. For example, if the computing device is in a loud location, the computing device may allow for slightly louder noise levels than the noise level selected by the user. The additional noise may be undetectable over the background noise. Thus, the present disclosure provides a way to control the speeds of air moving devices based on user selected noise levels, rather than being limited to predetermined levels associated with limited performance options.

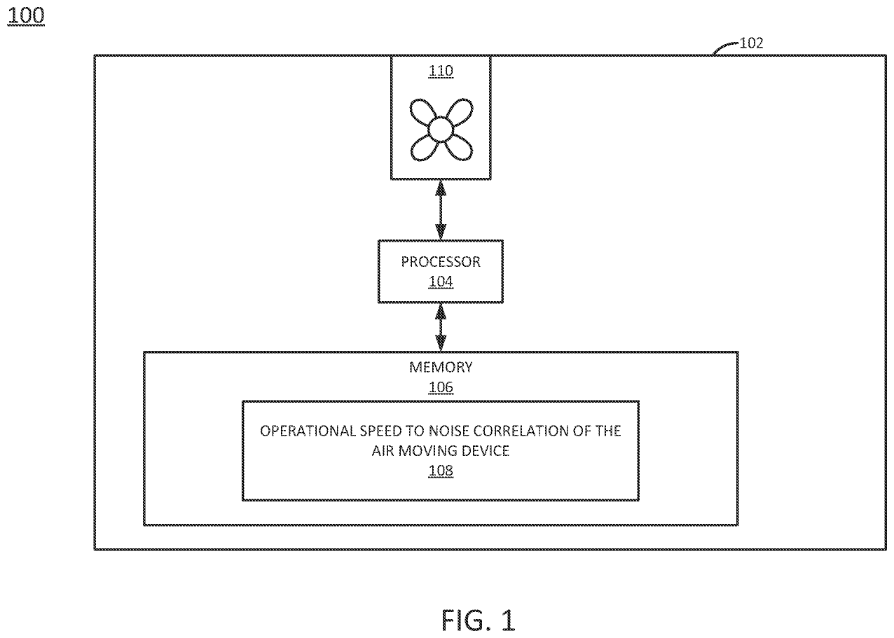

FIG. 1 illustrates an example apparatus 100 of the present disclosure. In an example, the apparatus 100 may be a computing device ora computing system. For example, the apparatus 100 may be a desktop computer, a laptop computer, a tablet computer, and the like.

It should be noted that apparatus 100 has been simplified for ease of explanation. Although various example components are illustrated in FIG. 1, it should be noted that the apparatus 100 may include additional components that are not shown. For example, the apparatus 100 may include input/output devices (e.g., a display, a monitor, a keyboard, a mouse, a trackpad, and the like), a power supply, various interfaces (e.g., a universal serial bus (USB) interface), communications interfaces (e.g., a wired or wireless communication interface such as WiFi, Ethernet, and the like), and so forth.

In an example, the apparatus 100 may include a housing 102. The housing 102 may enclose a processor 104, a memory 106, and an air moving device 110. The processor 104 may be communicatively coupled to the memory 106 and to the air moving device 110. The processor 104 may access information or execute instructions that are stored in the memory 106. The processor 104 may also control operation of the air moving device 110.

In an example, the processor 102 may be a general purpose processor or an application specific processor, such as one that is dedicated to the health management of the apparatus 100. In an example, the air moving device 110 may be a fan, a blower, or any other mechanical device that can be controlled to circulate air within the housing 102.

In an example, the memory 106 may be any type of non-transitory computer readable medium. For example, the memory 106 may be a random access memory (RAM), a read-only memory (ROM), a solid state drive, a hard disk drive, a non-volatile memory express (NVMe) device, and the like. The memory 106 may store various instructions that can be executed by the processor 104 to perform the functions described herein or may store data that can be used by the processor 104 to make decisions on how the air moving device 110 should be operated.

An example of the data that can be stored includes an operational speed-to-noise correlation of the air moving device 110 (hereinafter also referred to as a noise correlation 108). The noise correlation 108 may provide pre-measured data or tables that indicate an amount of noise generated by the air moving device 110 (e.g., in decibels) at different operational speeds of the air moving device 110. Although a single noise correlation 108 is illustrated in FIG. 1, it should be noted that different noise correlations 108 may be stored for different types or models of air moving devices 110. As a result, when a different air moving device 110 is installed, the memory 106 may have the proper air moving device correlation 108 for the newly installed air moving device 110.

In an example, the noise correlation 108 may be used to set an operational speed of the air moving device 110 based on a user selected noise level. For example, different noise levels may be presented to a user. Each noise level may be a value of one of a plurality of pre-determined noise level values associated with a different operational speed of the air moving device 110 in accordance with the noise correlation 108.

For example, the user may be presented with noise levels of quiet, normal, or max performance (loud). Quiet mode may be associated with a noise level below a first decibel threshold, the normal mode may be associated with a noise level below a second decibel threshold, and the max performance mode may have no noise limits. It should be noted that the noise levels may be presented in other ways. For example, the noise level may be presented as a numerical value between 1 and 5, or a range of degrees (e.g., minimum, moderate, maximum), and the like. The way the noise levels are presented is not limited to the examples provided herein.

The user may select a noise level, and the user selected noise level may be received by the processor 104. The processor 104 may look up the operational speed or range of operational speeds associated with the user selected noise level. The processor 104 may then operate the air moving device 110 at a speed that maintains the noise level at or below the decibel threshold associated with the noise level that was selected by the user.

In an example, the presented noise levels may be accompanied by an example operational speed and noise of the air moving device 110. For example, when the user selects a “quiet mode,” the processor 104 may operate the air moving device 110 at the operational speed associated with the “quiet mode” so the user can hear how loud the air moving device 110 would be in the “quiet mode.” When the user selects a “normal mode,” the processor 104 may operate the air moving device 110 at the operational speed associated with the “normal mode” so the user can hear how loud the air moving device 110 would be in the “normal mode,” and so forth. Thus, the user may be provided with examples of how loud the air moving device would be when cycling through the available noise level selections to help the user select a desired noise level.

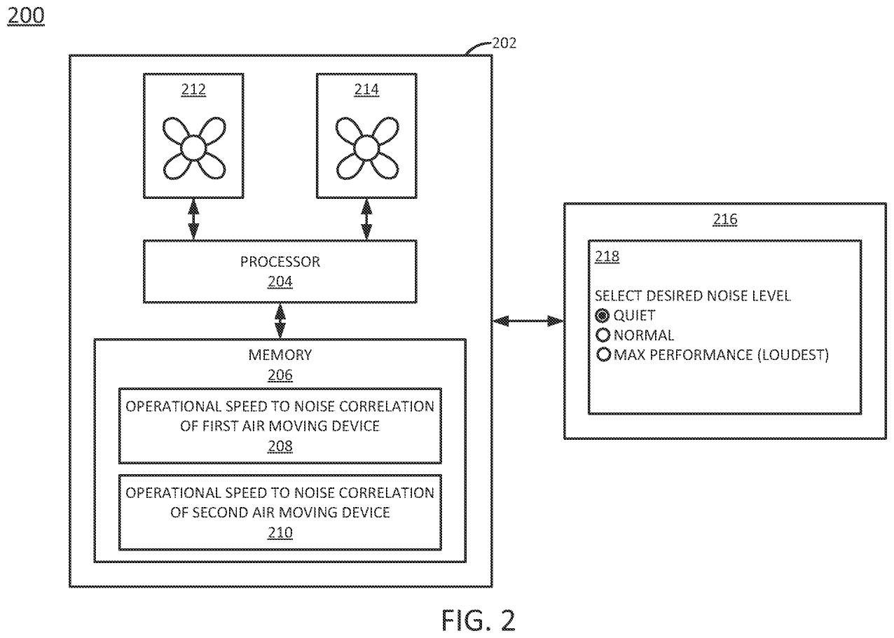

FIG. 2 illustrates another example apparatus 200. In an example, the apparatus 200 may be a computing device or a computing system. For example, the apparatus 200 may be a desktop computer, a laptop computer, a tablet computer, and the like.

It should be noted that apparatus 200 has been simplified for ease of explanation. Although various example components are illustrated in FIG. 2, it should be noted that the apparatus 200 may include additional components that are not shown. For example, the apparatus 200 may include input/output devices (e.g., a touch screen interface, a keyboard, a mouse, a trackpad, and the like), a power supply, various interfaces (e.g., a universal serial bus (USB) interface), communications interfaces (e.g., a wired or wireless communication interface such as WiFi, Ethernet, and the like), and so forth.

In an example, the apparatus 200 may include a housing 202 that encloses a processor 204, a memory 206, and air moving devices 212 and 214. In an example, the processor 204 may be communicatively coupled to a display 216. The display 216 may be an external display or may be part of the housing 202 (e.g., a display that is part of a laptop computer).

In an example, the processor 204 may be communicatively coupled to the memory 206 and to the air moving devices 212 and 214. The processor 204 may access information or execute instructions that are stored in the memory 206. The processor 204 may also control operation of the air moving devices 212 and 214.

In an example, the memory 206 may be any type of non-transitory computer readable medium. For example, the memory 206 may be a random access memory (RAM), a read-only memory (ROM), a solid state drive, a hard disk drive, a non-volatile memory express (NVMe) device, and the like. The memory 206 may store various instructions that can be executed by the processor 204 to perform the functions described herein or may store data that can be used by the processor 204 to make decisions on how the air moving devices 212 and 214 should be operated.

An example of the data that can be stored includes an operational speed-to-noise correlation of the air moving device 212 (hereinafter also referred to as the first noise correlation 208) and an operational speed-to-noise correlation of the air moving device 214 (hereinafter also referred to as the second noise correlation 210). The first noise correlation 208 may provide pre-measured data or tables that indicate an amount of noise generated by the first air moving device 212 (e.g., in decibels) at different operational speeds of the first air moving device 212. The second noise correlation 210 may provide pre-measured data or tables that indicate an amount of noise generated by the second air moving device 214 (e.g., in decibels) at different operational speeds of the second air moving device 214. As noted above, the memory 206 may store a plurality of different noise correlations for different types or models of air moving devices that can be deployed within the housing 202 to help cool the apparatus 200.

In an example, the first noise correlation 208 may be used to set an operational speed of the first air moving device 212, and the second noise correlation 210 may be used to set an operational speed of the second air moving device 214 based on a user selected noise level.

For example, the display 216 may provide a graphical user interface (GUI) 218 that presents different noise levels to a user. Each noise level may be a value of one of a plurality of pre-determined noise level values associated with a different operational speed of the air moving devices 212 and 214 in accordance with the first noise correlation 208 and the second noise correlation 210, respectively.

For example, the user may be presented with noise levels of quiet, normal, or max performance (loud) in the GUI 218. The user may select a noise level, and the user selected noise level may be received by the processor 204. The processor 204 may look up the operational speed or range of operational speeds associated with the user selected noise level. The processor 204 may then operate the air moving devices 212 and 214 at a speed that maintains the noise level at or below the decibel threshold associated with the noise level that was selected by the user. In other words, the processor 204 may set a maximum allowable operational speed of the air moving devices 212 and 214 based on an operational speed range determined by the user selected noise level using the first noise correlation 208 and the second noise correlation 210.

In an example, the total noise level attributed to a single air moving device 212 or 214 may be computed in accordance with Equation (1) below:

SoundPressure=a·log₁₀(Speed)+b Equation (1)

where SoundPressure is the noise level in decibels, Speed is the operating speed of the air moving device 212 or 214, and a and b are constants. The relationship between SoundPressure and Speed may be a logarithmic curve that is stored as the first noise correlation 208 and the second noise correlation 210.

The value or amount of noise for a particular operating speed of the air moving devices 212 and 214 can be found in the first noise correlation 208 and the second noise correlation 210. In an example, the total amount of noise attributed to each air moving device 212 and 214 may be computed in accordance with Equation (2) below.

$${SoundPressure}_{Total} = 10 \cdot {log}_{10} [ {k}_{1} \cdot {10}^{( \frac{{Noise}_{1}}{10} )} + {k}_{2} \cdot {10}^{( \frac{{Noise}_{2}}{10} )} + … + {k}_{n} \cdot {10}^{( \frac{{Noise}_{n}}{10} )} ] , \qquad Equation ( 2 )$$

where Noise₁-Noiseₙ are the noise values found for each noise source (e.g., air moving device 212 and 214) using a corresponding noise correlation for each air moving device (e.g., the first noise correlation 208 and the second noise correlation 210 for the air moving devices 212 and 214, or noise correlations 1-n for air moving devices 1-n) and where values k₁-kₙ are weighting factors for each noise source Noise₁-Noiseₙ. For example, when k₁-kₙ are the same value, each noise source may contribute an equal amount of noise to the SoundPressure_{Total} (e.g., the total amount of noise in decibels).

Although the above examples are presented in terms of noise generated by the air moving devices, it should be noted that Equations (1) and (2) may be applied to any component within the apparatus 100 or 200 that may generate noise. For example, a correlation may also be created for the operation of a hard disk drive to an amount of noise generated. Thus, the correlations can be used to determine a noise contribution for each component that may generate noise, and the Equation (2) may be used to determine the total amount of noise.

In an example, the weighting factors k₁-kₙ may be different for different air moving devices. For example, the air moving device 212 may generate more noise than the air moving device 214. Thus, any noise generated by the air moving device 214 may be drowned out by the noise generated by the air moving device 212. In this instance, the weighting factor k for the air moving device 212 may be higher than the weighting factor k for the air moving device 214. In other words, the air moving device 214 may have to operate at a much louder level to contribute an equal amount of noise as air moving device 212.

In an example, weighting factors k₁-kₙ may be changed dynamically during operation of the apparatus 200. For example, when the apparatus 200 is initially operating, the air moving device 212 may be activated, and the air moving device 214 may not be activated. The weighting factor of the air moving device 212 may be 1. The air moving device 212 may operate at a speed associated with the user selected noise level. As the apparatus 200 continues to operate, the second air moving device 214 may be turned on to help cool the apparatus 200. The air moving device 214 may operate at a louder level than air moving device 212. Thus, the weighting factor for the air moving device 214 may be 0.75, and the weighting factor for the air moving device 212 may be decreased to 0.25. Notably, the weighting factors are changed during operation of the air moving devices 212 and 214, and the user selected noise level has not changed. The weighting factors are dynamically changed to ensure that the air moving devices 212 and 214 operate at a speed that meets the allowable amount of noise associated with the user selected noise level.

In an example, the air moving devices 212 and 214 may want to operate at a higher speed and generate more noise than the user selected noise level to ensure proper operation of the apparatus 200. For example, the user may have selected a “quiet mode,” but the user may be playing a video game that runs the processor 204 at high clock speeds and a graphics processor at high clock speeds that can generate large amounts of heat inside of the housing 202. The processor 204 may generate and present a notification to the user via the GUI 218 on the display 216. The notification may present the user with an option to change the user selected noise level (e.g., to maximum performance) to accommodate the higher temperatures. The notification may warn the user if that the user does not change the selected noise level, the performance of the apparatus 200 may be throttled or reduced to accommodate the “quiet mode” that is selected.

In an example, the noise levels may be presented to the user in a noise cycling presentation. For example, the GUI 218 may cycle through each level with an example noise level that is played to the user. The example noise level may be played from an audio file that is pre-recorded, or the air moving devices 212 and 214 may be operated at the speed to generate the associated noise level. The user may listen to the amount of noise for each noise level during the cycling presentation. The user may then select one of the noise levels after hearing all of the different noise levels from the cycling presentation.

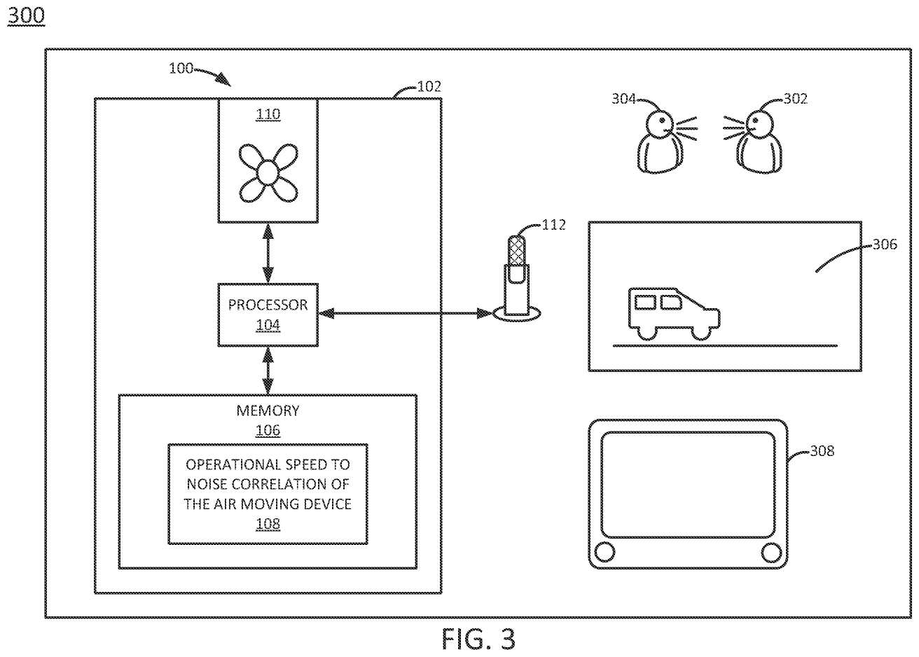

FIG. 3 illustrates an example environment 300 where the apparatus 100 may be deployed. In an example, the apparatus 100 may include a microphone 112. The microphone 112 may be communicatively coupled to the processor 104. The microphone 112 can record background noises. Examples of background noises may include background conversation between a person 302 and a person 304, traffic noises 306 outside of a window, background noise from a television 308 or another electronic device, and the like. It should be noted that FIG. 3 illustrates a few examples of background noises, and many other types of background noises may be recorded by the microphone 112.

The noise level of the background noise can be determined by the processor 104 based on the recorded background noises received from the microphone 112. The processor 104 may then adjust the allowable noise level of the air moving device 110 to select the operational speed of the air moving device 110 based on the desired noise level selected by a user.

For example, when the apparatus 100 is deployed in a library that is very quiet, the noise generated by the air moving device 110 may be noticeable. However, if the apparatus 100 is deployed in a loud environment with large amounts of background noise, the noise level of the air moving device 110 may not be as noticeable. Thus, in loud environments, the air moving device 110 may be able to operate at a louder level for a desired noise level selected by a user without the user noticing the louder operation of the air moving device 110.

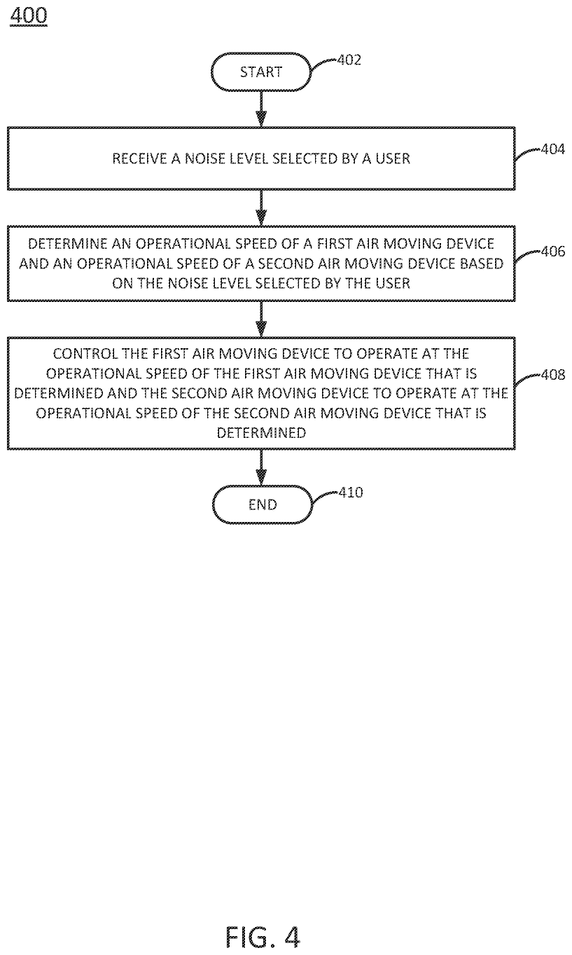

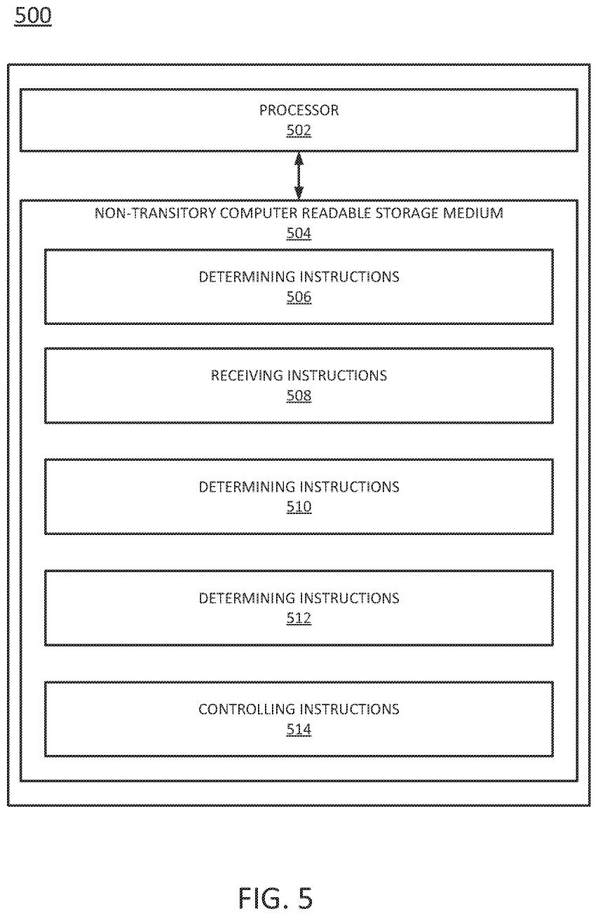

FIG. 4 illustrates a flow diagram of an example method 400 for controlling a speed of an air moving device of a computing device based on a user selected noise level by the apparatus 100 illustrated in FIG. 1, the apparatus 200 illustrated in FIG. 2, or the apparatus 500 illustrated in FIG. 5, and described below.

At block 402, the method 400 begins. At block 404, the method 400 receives a noise level selected by a user. For example, the user may select one of a plurality of different noise levels. Each noise level may be a value (e.g., a decibel value) of one of a plurality of predetermined noise level values associated with different operational speeds of an air moving device or multiple air moving devices of the computing device.

In an example, the different noise levels may be presented to the user in a GUI. The different noise levels may be presented via a cycling presentation that allows a user to hear a difference between the different noise levels before selecting a noise level.

At block 406, the method 400 determines an operational speed of a first air moving device and an operational speed of a second air moving device based on the noise level selected by the user. In an example, the operational speed of the first air moving device may be determined based on a correlation of the noise level selected by the user and an operational speed-to-noise correlation of the first air moving device. The operational speed of the second air moving device may be determined based on a correlation of the noise level selected by the user and an operational speed-to-noise correlation of the second air moving device.

In an example, the operational speed of the first air moving device and the second air moving device may be adjusted based on an amount of background noise that is detected. For example, a microphone may record background noise. The processor of the computing device may analyze the background noise to determine a noise level associated with the background noise. If the background noise is louder than the selected noise level, then the amount of noise allowable by the first air moving device and the second air moving device may be adjusted (e.g., increased), as the slight increase may be unnoticeable by the user given the background noise.

In an example, the background noise can be continuously monitored. Thus, as the background noise level changes, the computing device may continuously adjust the allowable noise level to meet the selected noise level.

In an example, the operational speed of the first air moving device and the operational speed of the second air moving device may be determined using Equations (1) and (2) described above. For example, weighting factors may be applied to determine the total amount of noise. The operational speed of the first air moving device and second air moving device may be adjusted based on the respective weighting factors applied to the first air moving device and the second air moving device.

At block 408, the method 400 controls the first air moving device to operate at the operational speed of the first air moving device that is determined and the second air moving device to operate at the operational speed of the second air moving device that is determined. At block 410, the method 400 ends.

FIG. 5 illustrates an example of an apparatus 500. In an example, the apparatus 500 may be the apparatus 100 or 200. In an example, the apparatus 500 may include a processor 502 and a non-transitory computer readable storage medium 504. The non-transitory computer readable storage medium 504 may include instructions 506, 508, 510, 512, and 514 that, when executed by the processor 502, cause the processor 502 to perform various functions.

In an example, the instructions 506 may include determining instructions 506. For example, the instructions 506 may determine a level of background noise. For example, a microphone may record various background noise to determine a total noise level of the background noise.

The instructions 508 may include receiving instructions. For example, the instructions 508 may receive a noise level for the apparatus selected by a user. A user may select one of a plurality of different noise levels.

The instructions 510 may include determining instructions. For example, the instructions 510 may determine an adjusted noise level based on the level of the background noise and the noise level selected by the user. For example, the user may select a “quiet” mode that is associated with a first noise level of operating air moving devices. The background noise that was captured may have a second noise level. The second noise level of the background noise may be higher than the first noise level associated with the operating air moving devices. Thus, the allowable noise level of the operating air moving devices may be adjusted to be slightly higher as the higher noise level may be undetectable given the amount of background noise.

The instructions 512 may include determining instructions. For example, the instructions 512 may determine an operational speed of an air moving device based on the adjusted noise level. The adjusted noise level may be used to determine the operational speed of the air moving device using the operational speed to noise correlation of the air moving device that are stored in memory.

The instructions 514 may include controlling instructions. For example, the instructions 514 may control the air moving device to operate at the operational speed that is determined.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

1. An apparatus, comprising:
an air moving device to cool the apparatus;
a memory to store an operational speed-to-noise correlation of the air moving device; and
a processor communicatively coupled to the air moving device and to the memory, wherein the processor is to:
receive a noise level selected by a user;
determine an operational speed of the air moving device based on the noise level selected by the user and the operational speed-to-noise correlation of the air moving device; and
control the air moving device to operate at the operational speed that is determined.

2. The apparatus of claim 1, wherein the air moving device comprises a plurality of air moving devices.

3. The apparatus of claim 2, wherein the memory is to store a function that calculates a total amount of noise based on a weighted contribution for each one of the plurality of air moving devices.

4. The apparatus of claim 2, wherein the memory is to store a respective operational speed-to-noise correlation for each one of the plurality of air moving devices.

5. The apparatus of claim 1, further comprising:
a microphone to measure an amount of background noise, wherein the noise level selected by the user is adjusted to be a higher noise level when the background noise is greater than the noise level selected by the user.

6. The apparatus of claim 1, further comprising:
a user interface to present different selectable noise levels to a user as the processor cycles the air moving device through different operational speeds associated with the different selectable noise levels presented to the user.

7. A method, comprising:
receiving, by a processor of a computing device, a noise level selected by a user;
determining, by the processor, an operational speed of a first air moving device and an operational speed of a second air moving device based on the noise level selected by the user; and
controlling, by the processor, the first air moving device to operate at the operational speed of the first air moving device that is determined and the second air moving device to operate at the operational speed of the second air moving device that is determined.

8. The method of claim 7, wherein the noise level comprises a value of one of a plurality of pre-determined noise level values associated with different operational speeds of the first air moving device and the second air moving device.

9. The method of claim 7, wherein the noise level is selected from a noise cycling presentation.

10. The method of claim 9, wherein the noise cycling presentation cycles through different air moving device speeds of the first air moving device and the second air moving device to present different noise levels to the user.

11. The method of claim 7, wherein the operational speed of the first air moving device and the operational speed of the second air moving device are determined based on an operational speed-to-noise correlation for the first air moving device and an operational speed-to-noise correlation for the second air moving device, respectively.

12. The method of claim 11, wherein the first air moving device is associated with a first weighting factor and the second air moving device is associated with a second weighting factor.

13. The method of claim 12, wherein a maximum speed for the first air moving device is selected based on the operational speed-to-noise correlation for the first air moving device and the first weighting factor, and a maximum speed for the second air moving device is selected based on the operational speed-to-noise correlation for the second air moving device and the second weighting factor to allow a total noise level to be below the noise level selected by the user.

14. The method of claim 12, wherein the first weighting factor and the second weighting factor are dynamically changed during operation of the computing device.

15. A non-transitory computer readable storage medium encoded with instructions which, when executed, cause a processor of an apparatus to:
determine a level of background noise;
receive a noise level for the apparatus selected by a user;
determine an adjusted noise level based on the level of the background noise and the noise level selected by the user;
determine an operational speed of an air moving device based on the adjusted noise level; and
control the air moving device to operate at the operational speed that is determined.

16. The non-transitory computer readable storage medium of claim 15, wherein the adjusted noise level is greater than the noise level selected by the user when the level of background noise is greater than the noise level selected by the user.

17. The non-transitory computer readable storage medium of claim 15, wherein the level of background noise comprises an average amount of background noise measured during a predefined time period.

18. The non-transitory computer readable storage medium of claim 15, wherein the noise level selected by the user is received from a selection made during an air moving device speed/noise cycling operation.

19. The non-transitory computer readable storage medium of claim 15, wherein the operational speed is determined based on an operational speed-to-noise level correlation for a type and a model of the air moving device.

20. The non-transitory computer readable storage medium of claim 15, wherein the operational speed is determined based on an amount of noise contributed by a second air moving device and the adjusted noise level.
